(19) United States
(12) Patent Application Publication
(10) Pub. No.: US 2004/0039912 A1
(43) Pub. Date: Feb. 26, 2004

(54) Computer networked system and method of digital file management and authentication

(75) Inventors: Colin D. Borrowman, Schenectady, NY (US); John T. Botti, Loudonville, NY (US)

Correspondence Address: Clifford Chance US LLP, 200 Park Avenue, New York, NY, 10166-0153, US

(73) Assignee: Bitwise Designs, Inc. to AuthentiDate Holding Corp.

(21) Appl. No.: 10/374,320

(22) Filed: Feb. 26, 2003

Related U.S. Application Data
(63) Continuation of application No. 09/562,735, filed on May 1, 2000, now abandoned.
Application No. 09/562,735 is a continuation-in-part of application No. 09/259,135, filed on Feb. 26, 1999, now abandoned.

(51) Int. Cl. H03M 13/00

(52) U.S. Cl. 713/176; 707/1; 714/758

(57) ABSTRACT

The digital file management system and method of the present invention provides a processing service that may be located remotely on a computer network that receives digital files from users and performs file identification, authentication and verification, including time, digital signature, and image marking. The system and method may include the remote processing and storage of file information such that the user does not need to maintain any application specific software at the user's local site. The system and method may record additional independent data with each stored image including: a “true date” gleaned from a secure clock which is not settable by the user (the Authentidate™); a number derived from a cyclic redundancy code (CRC) algorithm against the image data; (the “image CRC”); and a CRC derived from the “true date”, (the “date CRC”). This additional data may be recorded within each digital file as soon as possible after the file is acquired. If the file is altered after the recording of the additional data, recalculation of the image CRC on the altered file will not match the original image CRC recorded within it. Thus, that the file was altered can be detected. Likewise, if the true date is altered in any way, recalculation of the date CRC will similarly reveal this fact. The image and date CRCs can be checked and verified at any time. If the recalculated value matches the recorded value, the image can be verified as being recorded on the specified date and has not been altered since that time.

### CROSS-REFERENCE TO RELATED APPLICATIONS

This application is a continuation-in-part of U.S. Ser. No. 09/259,135 filed Feb. 26, 1999.

### FIELD OF THE INVENTION

This invention relates generally to digital imaging systems and more particularly to digital file authentication.

### BACKGROUND OF THE INVENTION

Digital imaging is the representation, and storage, of an image or object as a digital raster image. Digital imaging is increasingly used in many industries, partly because of the increased availability of enabling technology and partly due to the many advantages offered over conventional storage methods including: reduced storage space, increased access speed, focused retrievability (e.g., search capabilities), the ability to conveniently make “multiple” and “backup” copies of documents, and the ability to transfer or transmit documents quickly.

In the case of paper document originals, digital imaging systems will typically scan the paper document and store a representation of the scanned document as a digital raster image. An optical scanning device is typically used to scan images of the paper originals for storing as a digital image. The scanned images are exact representations of the original (limited only by the resolution limit of the scanning device), and can include handwriting, signatures, photos, figures, etc. Alternatively, digital images originating from digital cameras, medical imaging devices, or other sources may also be stored in a digital imaging system.

One drawback of known imaging technology is the inherent ability of digital images to be altered, for example, with a purpose to defraud. For example, although an original paper document can be tampered with, such tampering (erasure or additions) will typically leave telltale evidence, digital images of those documents, on the other hand, can be perfectly altered leaving no such evidence. Thus, where the authenticity of an image is critical and may come into question (e.g., legal and medical fields), use of digital images is often not preferred, not acceptable or not admissible and therefore often avoided.

While many different digital image formats are available, in each case, the data is potentially alterable. Even if the digital imaging system does not explicitly provide an editing function, the images can be edited with a third party tool.

A proposed solution is the use of Write-Once, Read-Many (“WORM”) optical media to store digital images. One advantage of WORM media storage is that the data it houses is inherently unalterable data can be written only one time to the medium. However, this approach has several disadvantages as well. For example, data recorded on WORM media can be copied from the WORM disk of original recording to re-writable media, altered, and then recorded on new WORM disk with no traceability of such events.

Additionally, although it can be stated with great confidence that data on any one particular WORM disk has not been altered since it was recorded on that disk, the date and time when the data was recorded or whether the data matches an “original” of any kind cannot be determined with any certain or definitive means.

A known advance in file verification technology provides for registration of an “electronic signature” of a digital file (image, word processor document, audio or video clip, etc.). It is known to allow a user to locally select a file and locally run a program provided by a service provider to create an “electronic signature” of the selected digital file based solely on file content. The signature along with a user-provided file name and user-selected keywords are uploaded to the provider's site and stored in a registration database maintained by the service provider under an account established for the particular user. One particular provider generates a “certificate of registration” showing, inter alia, the signature.

Verification of content and submittal date of the digital file at a later time requires going on-line to access the service provider's site and retrieving the prior registration record by file name or keywords. The retrieved database record shows the file signature and the original date that the file signature was registered. To complete verification, the user must run (locally again) the electronic signature program on the file to be verified and compare the regenerated signature to the retrieved registered signature to determine whether the signature of the digital file in question matches that of the originally registered file.

What the user now has is verification that the signature of the file in hand matches the signature of a file which was registered on a particular date.

### SUMMARY AND OBJECTS OF THE INVENTION

The foregoing and other problems and deficiencies in image authentication in known digital imaging systems are solved and a technical advance is achieved by the present invention for providing digital file authentication by secure image marking.

In various aspects, it is among the objects of the present invention to provide a system and method for digital file management providing digital file authentication by secure file marking.

A digital file management system in one embodiment of the present invention comprises means for inputting a digital file and a secure date and time reference providing date and time information. A date/time value is generated which is derived from the secure date and time information. An image value is derived from the digital file itself. The digital file is marked with the date and time information, the date/time value and the image value. The marked digital file is then stored.

Alternative embodiments can include such features as generating the date/time value and image value by a cyclic redundancy code algorithm and transforming the date/time value and image value via a mathematical transformation and marking the digital file with the transformed values.

In other embodiments, the secure date and time reference is a local secure clock.

In various embodiments, the digital file can be an image file, a text file or any other file format.

Alternative embodiments of the invention allow for inputting a digital image by way of an optical scanner for scanning an original image into a digital image or directly from digital cameras or medical imaging equipment. The marked digital file can also be stored in optical storage.

### BRIEF DESCRIPTION OF THE DRAWINGS

The foregoing and other features and advantages of the present invention will become more apparent in light of the following detailed description of exemplary embodiments thereof, as illustrated in the accompanying drawings, where

FIG. 1 illustrates a system implementation of the DocSTAR embodiment of the present invention;

FIG. 2 is a flow chart illustrating the file marking according to one embodiment of the present invention;

FIG. 3 is a flow chart illustrating validation of the CRCs in a filed marked image according to one embodiment of the present invention;

FIG. 4 is a flow chart illustrating one embodiment for setting the secure clock of the present invention;

FIG. 5 is a flow chart illustrating calculation of the Image CRC for TIFF format images according to one embodiment of the present invention;

FIG. 6 is a flow chart illustrating calculation of the Date CRC for TIFF format images according to one embodiment of the present invention;

FIG. 7 is a flow chart illustrating calculation of the Image CRC for JPEG format images according to one embodiment of the present invention; and

FIG. 8 is a flow chart illustrating calculation of the Date CRC for JPEG format images according to one embodiment of the present invention;

FIG. 9 illustrates a network based implementation according to an embodiment of the invention;

FIG. 10 is a flow chart illustrating the steps of an embodiment of the present invention.

### DETAILED DESCRIPTION OF THE INVENTION

The following description of the present invention uses for illustrative purposes the Authentidate™ image authentication system incorporated in the turn-key document management and imaging system, DocSTAR™, both of which are available from BitWise Designs, Inc, the assignee of the present invention. While the DocSTAR embodiment of the present invention is geared towards storing, marking and authenticating paper document originals, any digital file can be processed by the method and system of the present invention as will be described. The following discussion with references to the DocSTAR embodiment are in no way intended to be limiting and are made for illustrative purposes only to facilitate explanation and understanding of the present invention.

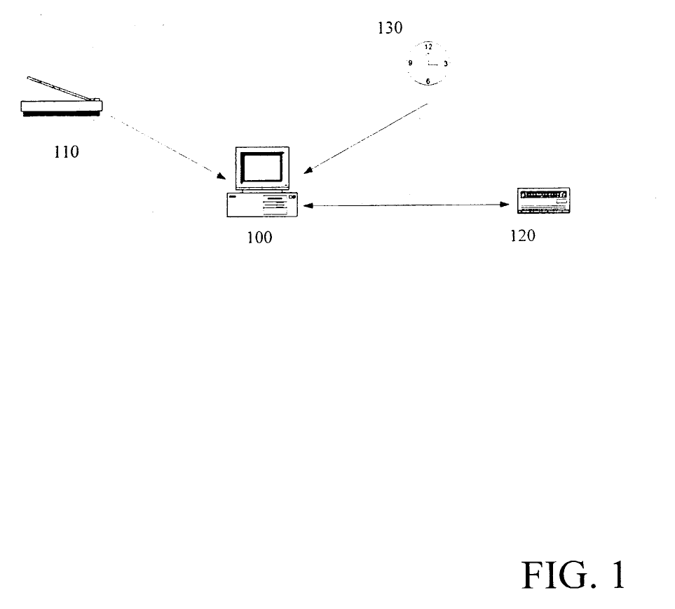

FIG. 1 illustrates an exemplary embodiment of the DocSTAR document management and imaging system implementation of the present invention.

A DocSTAR system host 100 is configured in communication with an input device 110, storage device 120 and a secure time and date reference 130.

In this embodiment, system host 100 is implemented as an IBM PC or workstation, input device 110 is an optical scanner, storage device 120 is an optical storage device and the secure time and date reference 130 is provided by a hardware key which incorporates a secure clock.

Original images will be scanned by optical scanner 110. The resulting digital image will be processed by system host 100 according to the method of the present invention which will be discussed in further detail herein, and then stored on optical storage device 120 from where it can be later retrieved.

The image authentication system of the present invention operates in one aspect by recording additional independent data with each stored digital file. These additional data includes: a “true date” which is gleaned from a secure clock (described in further detail below) which is not settable by the user (the Authentidate™); a number derived from a cyclic redundancy code (CRC) algorithm (described in further detail below) against the image data, this number is called the “image CRC”; and a CRC derived from the “true date”, called the “date CRC”.

These additional data are preferably recorded within each digital file as soon as possible after the image is acquired by the system (from, for example, scanner 110 in the DocSTAR embodiment). As will be discussed in further detail, if the image is altered in any way after the recording of the additional data, recalculation of the image CRC on the altered image will not match the original image CRC recorded within it. Thus, the fact that the image has been altered or is otherwise compromised can be detected. Likewise, if the true date is altered in any way, recalculation of the date CRC will similarly reveal this fact.

The image and date CRCs can be checked and verified at any time. If the recalculated value matches the recorded value, it can be stated with extreme confidence that the image presently recorded was recorded on the specified date and has not been altered in any way since then. No other known system, including paper storage, can offer similar assurance as to the creation date or authenticity of a document.

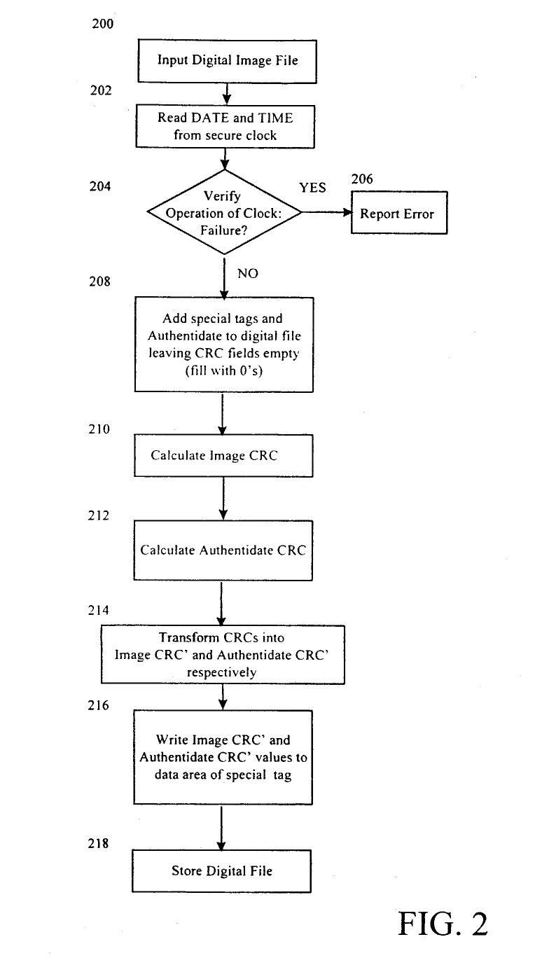

With reference to FIG. 2, the operation of the present invention will now be described.

Digital files are first acquired (either retrieved from storage or received from input device 110). (Step 200.) Date and time information is obtained from secure clock 130. (Step 202.) Proper operation of the secure clock is assessed. (Step 204.) If the secure clock is deemed functional, then the date and time data are accepted as read from the clock (in step 202). If a failure of the secure clock is determined, an error indication will be returned and the image processing is halted. (Step 206.) With the clock having been deemed functional (in step 204), special tags (as will be discussed infra) and the Authentidate information (including date and time) are added to the digital file and the CRC data fields are initialized to 0 (i.e., the data fields are filled with 0's). (Step 208.)

Two computed values are then calculated, which are derived from the image content and Authentidate information, respectively. The computed values can be computed in any fashion based on data contained within the digital file which will allow detection of data corruption, such as for example, a standard checksum. In this embodiment of the present invention, cyclic redundancy codes (“CRC”), essentially a more complex checksum calculation, are used to derive the computed values. Any calculation method, however, is acceptable which will provide a number which is derived from the document content data and is suitable for detection of data corruption.

In this embodiment, the computed values are generated by a known CRC algorithm (which will be discussed in further detail below) which is run on both the image content and the Authentidate, creating an Image CRC and an Authentidate CRC, respectively. (Steps 210, 212.) The Image CRC and Authentidate CRC are “transformed” by a proprietary mathematical transformation for added security (as will be discussed infra) creating an Image CRC′ and an Authentidate CRC′. (Step 214.)

The image file is then marked with the Image CRC′ and Authentidate CRC′. (Step 216.) The marked digital files are stored on optical media by optical storage device 120. (Step 218.)

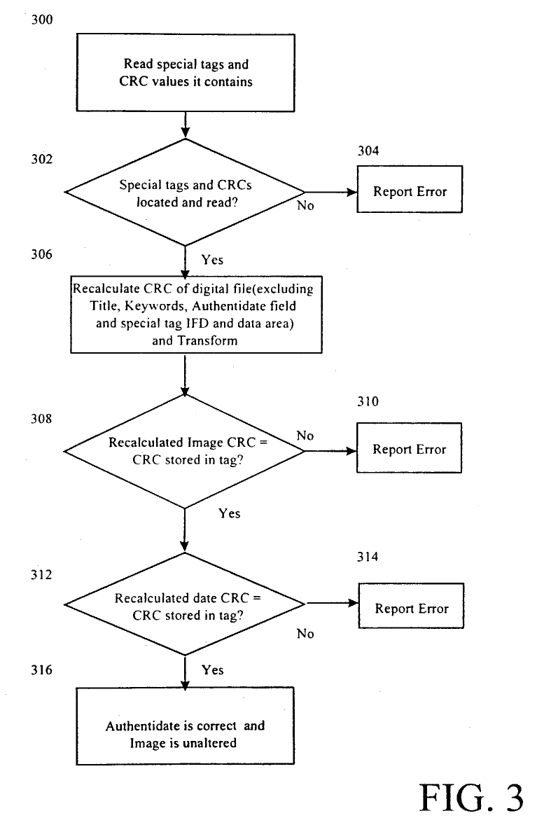

The authenticity of the image and the time and date stamp can then subsequently be determined by examining the computed values stored within the Digital Files as shown in FIG. 3 which depicts an exemplary flow chart describing one embodiment for validating CRCs in a filed image.

The first step in validating the CRCs in a digital file is to read the special tag and date areas and retrieve the stored image CRC and date CRC values. (Step 300.) If the CRC values cannot be located or read in the digital file (step 302), then, it is determined that either the image has not been properly filed or the image has been altered or is otherwise compromised, and an error is posted. (Step 304.) If the special tags are found, the CRCs are recalculated for the digital file and the date string. (Step 306.) The same algorithms used to calculate the CRCs initially are used to regenerate them at this point. The recalculated image CRC is transformed and compared to the image CRC read from the tag. (Step 308.) (Alternatively, the stored image CRC can be reverse transformed prior to comparison to the recalculated value.) If the recalculated digital file CRC does not match the one stored in the special tag, the image is determined to have been altered or otherwise be corrupted and an error is indicated. (Step 310.) If the stored and recalculated image CRCs compare favorably (i.e., they match), the date CRCs are tested. The recalculated date CRC is transformed and compared to the date CRC read from the tag. (Step 312.) (Alternatively, the stored date CRC can be reverse transformed prior to comparison with the recalculated value.) If the recalculated date CRC does not match the one stored in the special tag, the date string is determined to have been altered or be otherwise corrupted and an error is indicated. (Step 314.) If the date CRCs match, at this point both image and date CRCs have compared favorably, the digital file is determined to be unaltered and thus authenticated. (Step 316.)

As will be appreciated from the foregoing description, the use of a secure, non-compromisable clock is fundamental to the present invention. It serves as a secure time and date source which is not alterable by the user. The secure clock maintains the time and date even when the computer is turned off with the aid of a battery backup.

One could use either custom designed hardware or a commercially available product that offers a secure clock. In either case, a mechanism must be in place to prevent fraudulent or arbitrary date/time adjustment.

In the DocSTAR embodiment, a commercially available product that incorporates a secure clock into a physical hardware key is utilized (sometimes called a “dongle”). The hardware key connects to the computer's parallel port and can be accessed through an application programming interface (API) provided by the manufacturer.

The hardware key chosen for use in the DocSTAR embodiment of the present invention is the TIMEHASP-4 available from Aladdin Knowledge Systems, LTD. The security of the hardware key is protected by a custom ASIC chip (Application Specific Integrated Circuit), a unique set of passwords used only by the system provider (for example, BitWise Designs, Inc. the assignee hereof and a “provider” of the DocSTAR system) and advanced protection algorithms and anti-debugging technology in the manufacturer's programming interface and device drivers. This offers a high degree of security for the secure clock.

The current date and time are factory programmed into the secure clock contained within the hardware key during assembly of the DocSTAR Host computer. While any time setting may be used, the secure clock in this embodiment is set to Greenwich Mean Time (GMT) eliminating the need to adjust the clock for different local time zones or for daylight savings time.

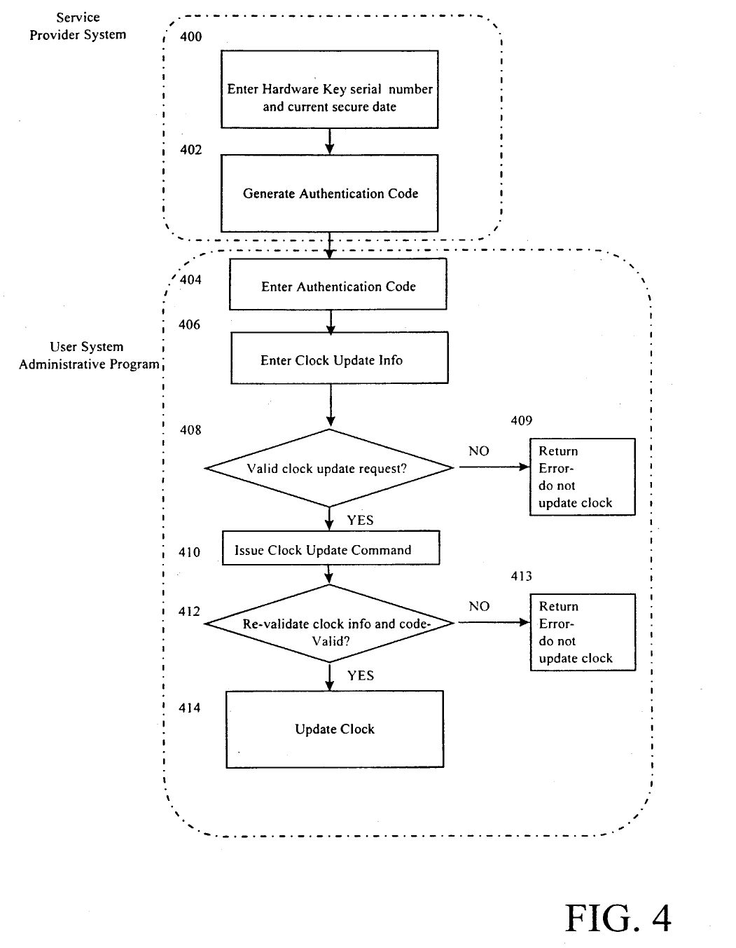

A mechanism can be incorporated to make adjustments in the clock to reset or correct the clock for slight inaccuracies that can develop over time. For example, in one embodiment as illustrated in FIG. 4, the date and time in the secure clock can be changed by means of a special administration program resident on a user's system which will only allow changes to the secure date and time when the user supplies a proper authentication code supplied by the system provider, such as, for example, the Technical Support department of BitWise Designs, Inc., the assignee hereof. The authentication code will only work to change the secure clock date and time from its current date and time values to the current GMT maintained by the system provider. This prevents the user from altering the secure clock arbitrarily and thereby stamping images with an incorrect or fraudulent date and time.

In this embodiment, an authentication code is required to change the secure clock. To obtain this code, a support technician on the system provider system enters the Hardware Key serial number and the current secure clock date into a secured custom program (the “Eagle Call Tracking System”) maintained at BitWise Designs, Inc. (step 400) which will generate an authentication code (step 402). The authentication code will allow the field technician or end user to change the secure clock only to the date and time established and maintained at BitWise Designs, Inc.

The authentication code in this embodiment is determined through a mathematical algorithm which yields one unique code given the current secure clock date, the hardware key serial number, and the desired change to date and time. This authentication code is of limited validity in that it will not work on another day in the future to reset the clock to the date and time on the day the authentication code was given.

The code is entered at the user end. (Step 404.) The desired clock setting is entered at the user end. (Step 406.) The administration program used on the client system allows a small time window (20 minutes) for which any time entered will match the authentication code. Authentication codes are calculated internally for times 5 minutes before and 15 after the given change to time. If the given authentication code matches any of the codes within the time window, the authentication code is deemed correct and implemented. This will allow a field technician to account for several minutes delay while the authentication code is communicated.

Thus the desired setting is validated against the authentication code to determine whether the code will authenticate the date and time change requested. (Step 408.) If invalidity is determined, an error is returned and the clock is not updated. (Step 409.) With a valid request, the actual change to the secure clock will not occur until the Update Clock command is entered at the user end. (Step 410.) This allows a field technician to accurately synchronize the field clock with the clock maintained at BitWise Designs, Inc. After the Update Command is issued, the authentication code is re-validated against the clock information to ensure it is still valid. (Step 412.) If invalidity is determined, an error is returned and the clock is not updated. (Step 413.) The clock is updated. (Step 414.)

Alternatively, secure clocks can be reprogrammed by the service provider at the provider's facility (e.g., BitWise Designs, Inc.) by attaching the hardware key directly to a designated Eagle system at BitWise Designs, Inc. and issuing the update secure clock command. The hardware key serial number is verified and the secure clock date and time are updated to GMT date and time maintained at BitWise Designs, Inc.

In further alternative embodiments, clock adjustments to correct for inaccuracies that can develop over time or to set the clock can be implemented as an automated process where a user can cause a clock update from a remote secure clock but the user cannot himself actually set the clock information.

Either the manual or automated method of clock setting and update described above will prevent the user from altering the secure clock arbitrarily and thereby stamping images with an incorrect or fraudulent date and time.

As can be expected within the limits of current available technology, the battery in each clock will eventually fail, or the clock can otherwise become defective over time. These conditions are tested by software prior to image processing to ensure that invalid dates from a defective clock (or dead battery) are not recorded in images, thus compromising the reliability of the image marking. In the event of a clock failure, image filing is disabled until the clock is repaired or replaced.

The computed values mentioned above with reference to FIG. 2, in the DocSTAR embodiment of the present invention are Cyclic Redundancy Codes (CRCs). The CRC is a 32 bit-integer value which represents the result of performing the known CRC-32 algorithm on a block of data. The CRC-32 algorithm is a common, public domain algorithm for detecting even minute changes in data with a variety of applications. For example, CRCs are used in the communications field to verify that data has been transmitted correctly over transmission lines of unknown quality. It is also used to detect corruption of compressed data such as in the popular PKZIP utility. One of the strengths of CRCs is detecting changes to data which might otherwise go undetected. For example, if bit errors occur in a given block of data but their sum is coincidentally the same as that of the original data, this error might go undetected if a standard checksum were to be used. The CRC-32 algorithm would detect this type of change because the resulting code is not simply a sum of the component data as in a standard checksum.

A technical discussion of the CRC-32 algorithm will not be presented here. There are many sources of CRC-32 algorithms and source code in the public domain. Sample C++ source code for a CRC32 algorithm which is implemented in the DocSTAR embodiment of the present invention, is attached as an appendix hereto. As stated earlier, use of the CRC is not required for the present invention per se, and any calculation method is acceptable which will provide a number which is derived from the image data and is suitable for detection of data corruption.

While a CRC value alone may be used, a higher level of security can be incorporated into the present invention to ensure the authenticity of an image by addition of a mathematical transformation to the CRC value. As indicated, a typical algorithm to calculate a CRC-32 is in the public domain and thus easily accessible. This fact, in conjunction with the details provided herein, would allow anyone to recalculate the CRC on an altered image, enabling them to counterfeit an “Authentidate” and falsely confirm the image as authentic and unaltered. In the present invention, the actual calculated (image or date) CRC is mathematically transformed to a new value prior to image marking. The functional requirements of the transformation are that the resultant value for any input value is consistent, and that the resultant value is unique for each unique input value. The transformation could, for example, be a permutation of the bit-order of the input, an exclusive OR of the input value with a consistent, predetermined “magic” number, or a combination of these operations.

While the particular transformation technique implemented is not critical, it should be understood that the specific technique used to accomplish the transformation in the practice of this invention should remain confidential to the provider, i.e., a “proprietary transformation technique”, as any disclosure or dissemination of the method would likely compromise system security and effectiveness. To give a simple parallel, failure to safeguard the proprietary transformation technique would essentially be the equivalent of password protecting a file and then distributing the password.

Recording information in tags within digital files requires knowledge of the individual digital file formats and the standards governing the structure of their formats. These standards dictate how information will be stored in the file, in what order, using what compression algorithm, etc. Most digital file formats have provisions for accommodating storage of user data in the digital file in addition to the image data. The DocSTAR file management and imaging system embodiment of the present invention uses known TIFF (Tagged Image File) and JPEG (Joint Photographic Experts Group) file formats for storage of (scanned) bitonal and color images, respectively. The standards for TIFF and JPEG image file formats allow for inclusion of user data inside the image file in a manner which does not affect the displayed image. As will be readily understood, the present invention is equally applicable to other file formats which have a mechanism to store user-defined data in the file or the file marked with the user-defined data can be stored in an ancillary file or separate database, for example, for word processing documents, spreadsheets, digitized audio or video or any other digitized file.

The known TIFF format is a file format which allows image data to be stored in a compressed manner along with information about the image (tags) such as compression method used, resolution, size, number of colors, title, date, etc.

A written world-wide standard defines the TIFF file format, what tags must be present, what tags are optional and how specific tags are used. The maintaining organization of the TIFF standard, Adobe Corporation, accepts requests for custom tag numbers for companies developing applications which use tags within the TIFF image. Adobe will assign unique numbers to individual companies to prevent interference between vendors. For example, BitWise Designs, Inc., the assignee hereof, applied for and was assigned its own proprietary tags numbers, other vendors will likewise be assigned their own unique proprietary tag numbers. Use of a custom tag allows storage of a custom data block. The TIFF specification calls for programs to ignore tags that they do not understand and which are not in the baseline specification. This allows common image viewers to view, display and print images which have custom tags because the image files still fit the TIFF specification.

In the case of TIFF image files, the following TIFF image tags are used:

| Tag # | Use |
|---|---|
| 10Dh | Document Name |
| 10Eh | Image Description |
| 132h | Date Time |
| 9244h | BitWise DocSTAR Custom Tag 1 |
| | custom data block contains propietary information including: |
| | Image CRC |
| | Authentidate CRC |

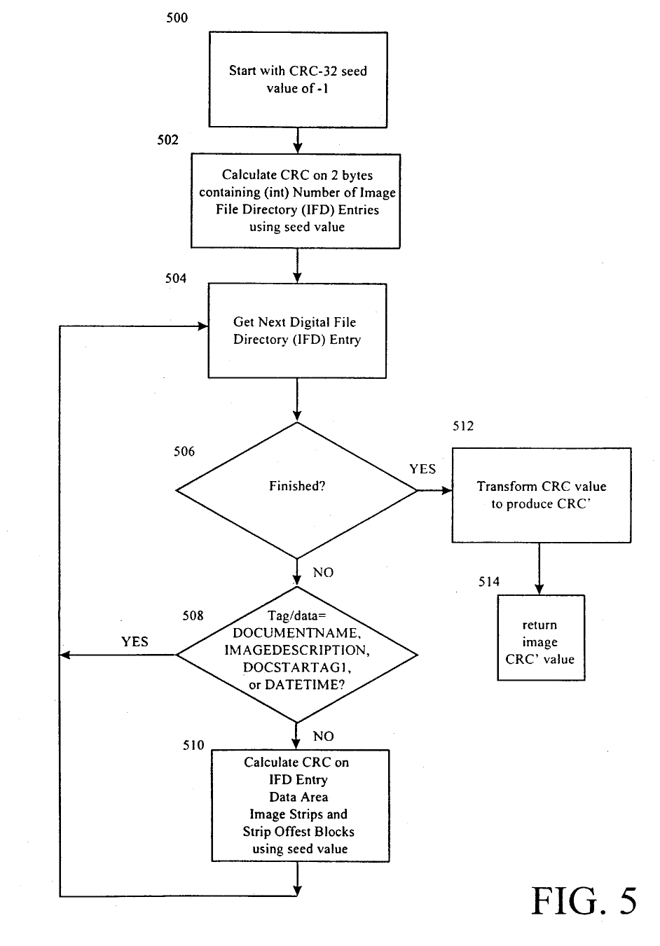

Illustrated in FIG. 5 is an exemplary flow chart demonstrating calculation of an image CRC for a TIFF image file. The calculation of the image CRC for the TIFF image file calls for calculating a CRC-32 on a given block of data using a given 32-bit seed value. The initial seed value is set to −1. (Step 500). The routine works through the format of the TIFF file based on the Image File Directory (IFD) for the file, calculating CRC-32 for each IFD entry and their associated data (step 502) passing results of the prior CRC-32 as the seed to the next (step 510) until all the IFD entries have been cycled through. (Step 506)

All tags and data areas are processed except the following tags and data areas (step 508):

| Tag # | Description |
|---|---|
| 0x010d | TIFFTAG_DOCUMENTNAME |
| 0x010e | TIFFTAG_IMAGEDESCRIPTION |
| 0x0132 | TIFFTAG_DATETIME |
| 0x9244 | TIFFTAG_DOCSTARTAG1 |

After processing all IFD entries for the file (step 506), the proprietary transformation method (as described above) is used to transform the resulting CRC value into a unique and secure value CRC′. (Step 512.) The transformed image CRC value, CRC′ is then stored in the image file. (Step 514.)

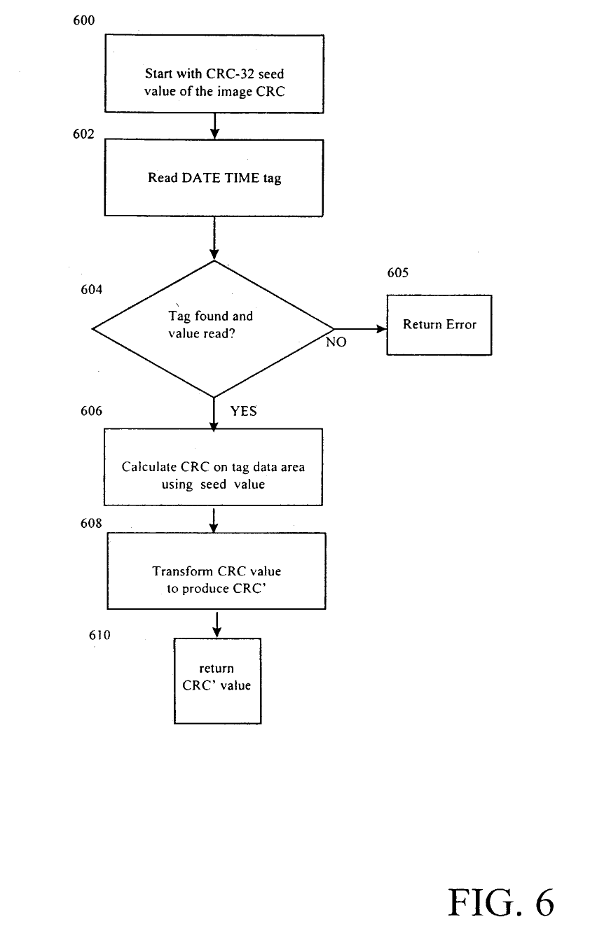

Illustrated in FIG. 6 is an exemplary flow chart demonstrating calculation of a date CRC for a TIFF image file. The calculation of the date CRC for the TIFF image file requires a routine which can calculate a CRC-32 on a given block of data using a given 32 bit seed value. The initial seed value is set to the image CRC value. (Step 600.) The routine reads the 0x0132 TIFFTAG_DATETIME tag. (Step 602.) If the DATETIME tag cannot be found and read (step 604), an error is returned (step 605), otherwise, a CRC-32 is calculated for the data contained within the DATE TIME tag. (Step 606.) The resulting CRC is then transformed into CRC′ by means of the proprietary transformation technique (step 608) and stored within the image file. (Step 610.)

The Joint Photographic Experts Group developed the namesake format and maintains the standard for JPEG and the JPG file format (sometimes also called JFIF—JPEG File Image Format). This format was developed for the storage and transmission of photographic images. The compression techniques used are ideally suited to storing subtle differences between color changes, such as a photograph.

As is known, a JPG file is interpreted as a stream of characters with special identifiers called “markers” separating different elements of the image information and image data. The exact meaning of each marker is not important to this discussion except that the JPG standard defines a set of markers to be used by manufacturers for special or proprietary features. These markers are named “APPx” where x is a digit between 0 and 9 inclusive.

The present invention adds a special marker and data block to JPG files when they are stored. In this embodiment, the “APP8” marker will be used for the simple reason that this marker is rarely used by other manufacturers. This marker holds various proprietary information including the following:

Authentidate

Image CRC

Authentidate CRC

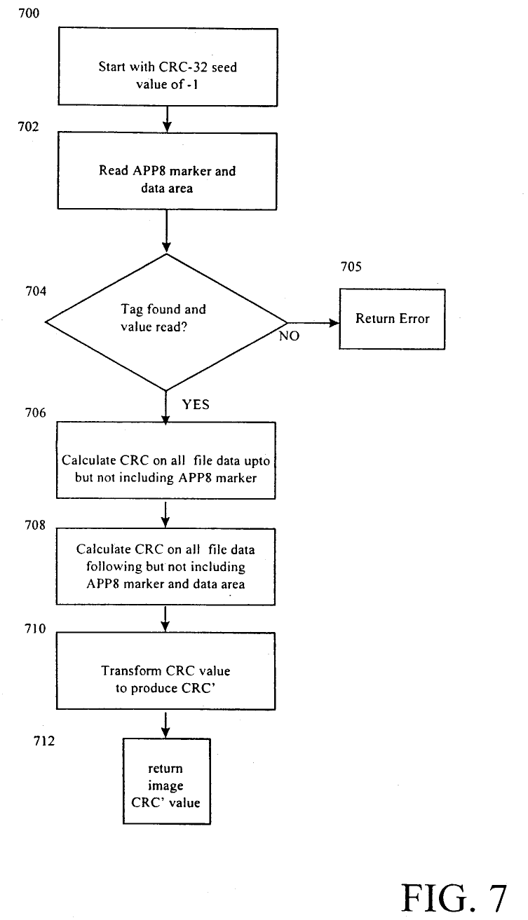

Illustrated in FIG. 7 is an exemplary flow chart demonstrating calculation of an image CRC for a JPEG image file. The calculation of the CRC for the JPEG image file requires a routine which can calculate a CRC-32 on a given block of data using a given 32-bit seed value. The initial seed value is set to −1. (Step 700.) The image file data is read sequentially and the position of the APP8 is determined and read. (Step 702.) If the APP8 marker cannot be found and read (step 704), an error is returned. (Step 705.) A CRC-32 is calculated for all data in the file from the beginning of the file up to but not including the APP8 marker. (Step 706.) The result of this calculation is used as a seed to calculate a CRC-32 on the remainder of the file following the APP8 marker. (Step 708.) The resulting CRC is transformed into CRC′ by means of the proprietary transformation technique. (Step 710.) The transformed image CRC′ is then stored within the image file. (Step 712.)

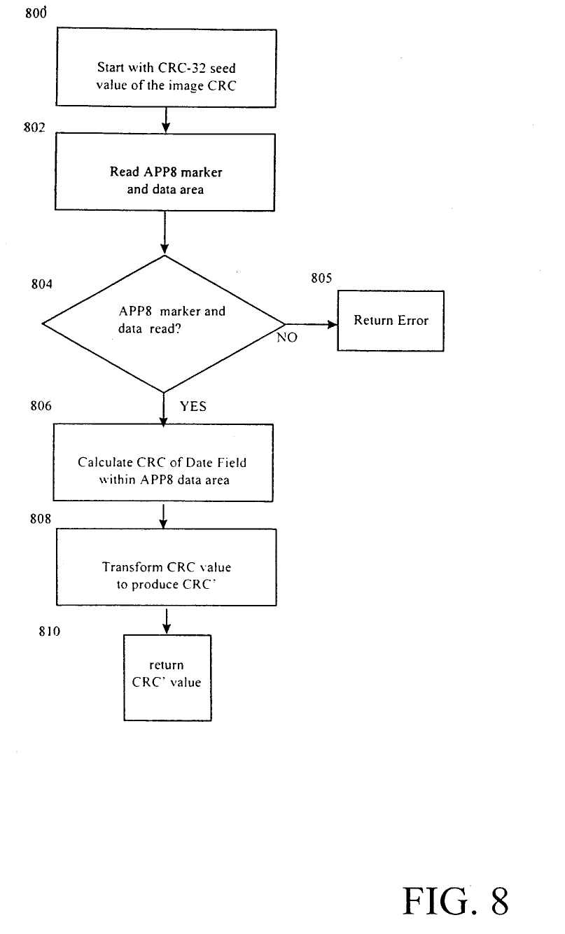

Illustrated in FIG. 8 is an exemplary flow chart demonstrating calculation of a date CRCs for a JPEG image file. The calculation of the CRC for the JPEG image file requires a routine which can calculate a CRC-32 on a given block of data using a given 32-bit seed value. The initial seed value is set to the image CRC value. (Step 800.) The file is read sequentially and the position of the APP8 is determined and read. (Step 802.) If the APP8 marker cannot be found and read (step 804), an error is returned. (Step 805.) A CRC-32 is calculated for the secure data string within the APP8 data area or block. (Step 806.) The resulting CRC is transformed into CRC′ by means of the proprietary transformation technique. (Step 808.) The transformed date CRC′ is stored within the image file. (Step 810.)

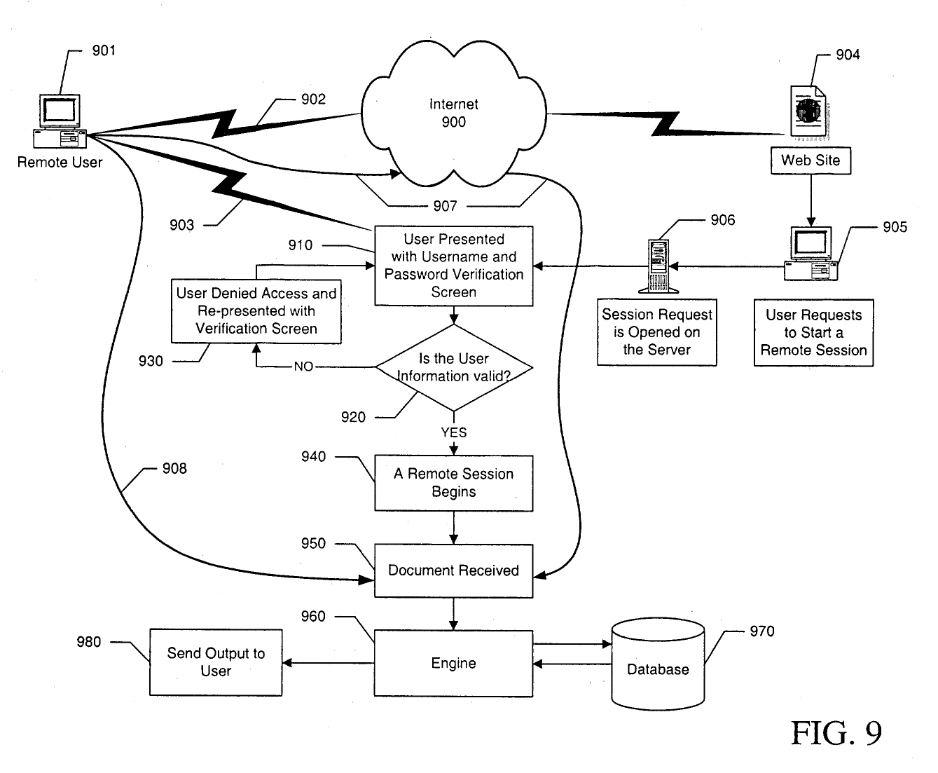

As shown in FIG. 9, an embodiment of the present invention includes using DocSTAR in a computer network environment such as the Internet 900. A user may link to an Authentidate server 906 by an Internet connection. An example of an Authentidate server 906 is a computer resource that provides Authentidate services such as determining a digital signature of a digital file, determining a time stamp associated with a digital file, or other processes as described herein. According to an embodiment of the invention, the user does not maintain or need any software specific to the Authentidate product or process. The user only needs to have access to the Internet, a direct dial-in connection with a modem, facsimile transmission capabilities, or other known means of making a digital connection to an Authentidate server 906. For example, the computer network could be a Local Area Network (“LAN”), a Wide Area Network (“WAN”), contained behind a firewall, a part of a larger computer network connected to the Internet, or combinations thereof. The user uploads a document to the Authentidate server 906 via whatever connection method the user chooses. The exemplary methods shown in FIG. 9 include an Internet connection 902 to a web site 904 maintained by the Authentidate server 906; a direct dial-in connection 903 to the Authentidate server 906 by, for example, a modem connection; submission of a document to the Authentidate server 906 by email 907; and submission to the Authentidate server 906 by facsimile transmission 908. The email connection 907 is illustrated as an email system that uses the Internet 900 to transmit data. It is also possible to use an email connection that does not use the infrastructure of the Internet 900. Other connections could include wireless connections, links through dedicated computer connections, dedicated hardwire connections, or any other methods for connecting to a computer server or uploading digital documents as are known in the art.

The system and user interface maintained on the Authentidate server 906 may include, as an option, a user registration and log-in procedure that requires verification of a username and password, as indicated in box 910. The system checks for validity of the user information (box 920), and either allows the user access to the service (box 940) or returns the user to the verification screen (box 930).

Once the user gains access to the Authentidate server 906, the user interface may provide the user with options for proceeding with the service. For example, the interface may provide an “upload document(s)” icon which provides that users may select a file from among those on the user's system. The user's document or file may be, for example, stored on the local computer's disk drive, the local computer's floppy disk drive, a server or network to which the user's computer is attached, or any other source to which the user has access.

The user uploads the file to be processed (box 950). The Authentidate server 906, may maintain all of the software and hardware to perform the service, which may be referred to generally as the engine 960. The engine 960 obtains a fingerprint or digital signature of the user's document by running a digital signature program or routine on the document, such as a cyclical redundancy code. Digital signature routines are known in the art and any routine may be selected for implementation into the system. After the engine 960 has obtained the digital signature of the document, the engine 960 may record the signature in a database 970.

According to one embodiment of the invention, the Authentidate server 906 maintains and runs the digital signature routine on the documents, and the user does not need to maintain any software particular to the Authentidate service. That is, the user does not need to maintain or access a clock or digital signature producing software, such as CRC software, but rather, needs only to be able to connect to a network or have access to a modem or some other uploading capability.

The Authentidate server 906 may maintain a master clock in order to accurately determine the time at which documents or files are delivered to the server. For example, an atomic clock which tracks Greenwich Mean Time (GMT) may be used to provide a robust and accurate time stamp for each file that is processed according to the present invention. Other clocks may be used for the purpose of recording a time stamp for each document processed, provided it is maintained for consistency and accuracy. The clock does not have to record GMT. Any time zone will suffice, so long as it is clearly specified. The time stamp may include a date, a time of day, a combination, or any other desired time criteria.

According to one embodiment of the invention, the time stamp is determined at the Authentidate server 906 as the time and date that the document was received by the Authentidate server 906 according to a master time clock at the Authentidate server 906 that is tied, for example, to an atomic clock for accuracy.

An alternative way to record a time stamp may be to record a number that represents a quantity of units of time from a selected date. For example, in the Unix Operating system, an integer number is used to record time represented as the number of seconds measured from a specific point in time. In a similar manner, the Authentidate server 906 could record a number that represents the number of minutes, the number of seconds, or some other unit of time, from a predefined point in time. For example, the time stamp could be a number that represents the total minutes from Jan. 1, 2000 at 12:00 am. The unit of measure may be chosen depending upon the degree of accuracy desired in the time stamp. For example, if time accurate to the second is desired, then the unit should represent seconds. If more or less accuracy is needed, then the unit should be smaller or larger as desired.

The Authentidate server 906 may send a record or receipt to the user who submitted the document, as indicated by box 980. The record may include, for example, the filename by which the document was submitted to the Authentidate server 906, a document identification number (ID Number) or identification tag, the time stamp, the digital signature, and a Reference field. The reference field may be specified by the user or alternatively, by the Authentidate server 906. For example, the reference field could be the subject line of a letter, the title of an agreement, a key phrase, or other suitable information that will be stored. The reference field may be useful in performing a search for the document.

The ID Number may be assigned by the Authentidate server 906 as a unique identifier for every document received by the Authentidate server 906. The ID Number, for example, could be a sequential number assigned incrementally as documents are received. It may be alphanumeric if desired, and may have information encoded, such as the year or date. By way of a non-limiting example, the ID Number may be coded by date, such as 052500-500 which could indicate the 500^{th} document received on May 25, 2000. The ID Number is not required for the present system to operate but rather, is one method which may be used for identification of documents.

Some alternative way of identifying documents rather than providing an ID number may be used. Providing a unique identification tag to a document is all that is needed, whether it is an ID number, a name, or some other unique tag means, it should be unique from other identification tags. Thus, for future reference, the ID number or identification tag is sufficient to allow the Authentidate server 906 to locate information that has been stored for a document. Alternative identification tags could include, for example, that documents or files may be tagged using the filename by which the document was provided to the Authentidate server 906 (which may or may not be unique from all other files uploaded) in combination with, for example, the time, date, or user associated with the upload document.

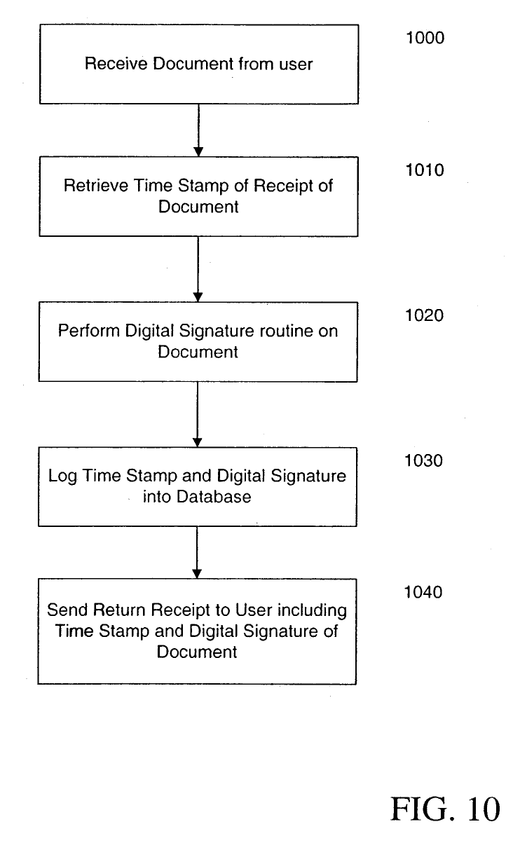

FIG. 10 shows a flow diagram of one embodiment of the present invention. The flow diagram shows exemplary steps, for which an actual implementation could include only some of, as well as additional process steps, for the engine 960 of FIG. 9. The Authentidate process includes receiving a document from a user (step 1000). When the document is received, the engine 960 will retrieve the time stamp to note the time of receipt of the document (step 1010). The engine 960 also performs the step of obtaining the digital signature of the document (step 1020). The information, that is, the time stamp and the digital signature, along with any other information that may be desirable, such as a document ID number, user identification information, or other document parameters, will be stored in a database maintained by the Authentidate service provider (step 1030). The engine, according to this embodiment, may also send a receipt to the user which includes the pertinent information relating to the submitted document, including, for example, the time stamp, the digital signature, the document ID number, or other information as desired (step 1040). The information could be provided to the user in any number of ways, including, without limitation, providing a web page with the users unique information, sending the receipt to the user via email, returning an information file over the users modem dial-in connection, or sending a receipt via U.S. Mail.

According to a further embodiment of the invention, the Authentidate server 906 may maintain a digital copy of the file as submitted in its entirety. The file could be saved in association with the log of information to be kept on the file such as the ID number, the time stamp and the digital signature. Alternatively, the digital document itself is not saved nor maintained by the Authentidate server 906. After the document has been processed in order to derive its digital signature, the document may be returned or deleted. For this alternative, a digital copy of the document is not maintained at the Authentidate site and the user is responsible for maintaining a digital copy of the document. In the future, the user or any third party (i.e. a second user) may submit a digital copy of the document, and the Authentidate server 906 can verify if the newly submitted document is the same as the document originally submitted by the user, and further can verify the date upon which the original document was originally submitted.

To verify whether a digital copy of a document is the same as the original document submitted by the user on the date and time recorded in the log, the Authentidate server 906 runs the digital signature routine on the document to be verified. This second digital signature is compared against the original digital signature, and if they are the same, then the Authentidate server 906 will issue notice that the document is verified. If the digital signatures are not the same, then the Authentidate server 906 will issue notice that the document is not verified.

A user wishing to verify a document may submit the document to Authentidate and request verification. The verifying user may submit the documents via Internet connection, direct dial modem, email, or any other way discussed above for the original user or known in the art. The verifying user may provide the Authentidate server 906 with the ID number of the original document (perhaps received from the original user that submitted the document), the file name, or some other identifying method by which the Authentidate server 906 may obtain the fingerprint of the original document. Authentidate may then run the digital signature program on the recently submitted digital copy of the document, and compare it with the digital signature or fingerprint of the originally submitted document. If the fingerprints compare favorably, then Authentidate will inform the third party that the document submitted matches the document as originally filed on the specified date.

According to one embodiment of the invention, some users may elect to have the original document stored by the Authentidate service. The Authentidate service would then be able to supply copies to the user or third parties upon request in the future. Along with a copy of the original document, the Authentidate service will be able to provide verification of the date upon which the document was submitted. The Authentidate service may require proper security authorization before distributing copies of any documents in order to provide security and maintain privileges of the original user.

It should be recognized that the process steps may occur in any appropriate order. For example, when a document is received, the time stamp may be determined and logged at that time, followed by running of the fingerprint routine, followed by logging of the document's fingerprint. Alternatively, the document may be received, the fingerprint may be determined, and then the time stamp and fingerprint may be logged substantially simultaneously.

As a further level of integrity and verification, the Authentidate server 906 may also perform digital signature routines on log files or database files generated by the Authentidate server 960 that contain the user information of various submitted documents. For example, the Authentidate server 906 may create a log file or database file that contains documents processed for a given period of time, such as a day or hour. For each document submitted and processed during the given time frame, the Authentidate server 906 records information such as the document ID, the user's name, the digital signature of the document, or any other information or parameters as discussed above.

The Authentidate server 906 may then perform a digital signature routine on the log file itself, and store the digital signature of the log file. At a later time, when a user wishes to verify a document for which a record was stored in the log file, the log file must be verified by comparing its digital signature to the digital signature of that log file at the time of storage of the information. Just as with the documents submitted by users, if the digital signature of the log file as originally stored matches the digital signature of the log file at the time of verification, then the log file is verified and the records stored for each of the various documents written to that log file are thus verified. If the log file digital signatures do not match, then the integrity of the log file has been compromised and the data contained therein (which includes the stored digital signature of user files) can not be relied upon. This level of integrity can be used, for example, to guard against tampering with the data.

The present invention has been illustrated and described with respect to specific embodiments thereof. It is to be understood, however, that the above-described embodiments are merely illustrative of the principles of the invention and are not intended to be exclusive embodiments. To facilitate discussion of the present invention, paper document originals (e.g., paper, photos, etc.) which are scanned into digital images are presumed in the DocSTAR embodiment of the present invention. However, it should be understood by one skilled in the art, that the present invention will be equally applicable to any digital file regardless of its source or how it is generated, for example, digital images originating from digital cameras, medical imaging devices, word processing or spreadsheet applications or other sources.

Alternative embodiments capturing variations in the enumerated embodiments disclosed herein can be implemented to achieve the benefits of the present invention.

It should further be understood that the foregoing and many various modifications, omissions and additions may be devised by one skilled in the art without departing from the spirit and scope of the invention.

It is therefore intended that the present invention is not limited to the disclosed embodiments but should be defined in accordance with the claims which follow.

What is claimed is:

1. A method of processing documents comprising the steps of:
receiving a document over a computer network from a remote user,
executing a routine to obtain a digital signature of the document,
logging the digital signature of the document in a database;
logging a time stamp associated with the document in the database.

2. The method of claim 1, further including the step of returning a receipt to the user, the receipt including the time stamp.

3. The method of claim 1, further including the step of returning a receipt to the user, the receipt including the digital signature.

4. The method of claim 1, further including the step of returning a receipt to the user, the receipt including a document identification tag.

5. The method of claim 1, wherein the computer network is the Internet.

6. The method of claim 1, wherein the document is received from the user over a direct dial-in modem connection.

7. The method of claim 1, wherein the document is received from the user by email.

8. The method of claim 1, wherein the time stamp represents the time that the document was received from the user.

9. The method of claim 1, wherein the step of logging the time stamp includes logging at least a time of day and a date.

10. The method of claim 1, wherein the step of logging the time stamp includes logging a number representing a quantity of units of measure of time from a predetermined point in time.

11. The method of claim 10, wherein the number represents a quantity of seconds from a predetermined point in time.

12. The method of claim 1, wherein the routine to obtain the digital signature of the document is a checksum routine.

13. The method of claim 1, wherein the routine to obtain the digital signature of the document is a cyclic redundancy code routine.

14. The method of claim 11, wherein the cyclic redundancy code is a CRC-32 routine.

15. A digital file management system comprising:
a storage device;
a processor connected to the storage device;
a timing device connected to the processor;
the storage device storing a program for controlling the processor; and
the processor operative with the program to:
receive an original document from a first user;
determine a time stamp from the timing device corresponding to the receipt of the original document;
perform a digital signature routine on the document to obtain an original digital signature;
record the time stamp and original digital signature associated with the original document in a database.

16. The apparatus according to claim 15, wherein the time stamp includes at least a time of day and a date.

17. The apparatus according to claim 15, wherein the time stamp includes a number representing a quantity of units of measure of time from a predetermined point in time.

18. The apparatus according to claim 15, wherein the digital signature routine is a checksum routine.

19. The apparatus according to claim 15, wherein the digital signature routine is a cyclic redundancy code routine.

20. The apparatus according to claim 19, wherein the cyclic redundancy code is a CRC-32 routine.

21. The apparatus according to claim 15, wherein the processor is further operative with the program to:
receive a second document from a second user;
perform a digital signature routine on the second document to obtain a second digital signature;
retrieve the original digital signature and original time stamp from the database;
perform a comparison of the second digital signature to the original digital signature; and
report a result from the comparison to at least one of the first user or the second user.

22. A digital file management system comprising:
a storage device;
a processor connected to the storage device;
a timing device connected to the processor;
the storage device storing a program for controlling the processor; and
the processor operative with the program to:
receive a digital file over a computer network from a user;
determine a time stamp from the timing device corresponding to the receipt of the digital file;
perform a digital signature routine on the digital file to obtain an image value corresponding to the digital file;
create a marked digital file by marking the digital file with the time stamp and the image value;
store the marked digital file in the storage device;
send a receipt to the user, the receipt including a digital file identification tag corresponding to the marked digital file.
